(19) United States
(12) Patent Application Publication
(10) Pub. No.: US 2025/0126785 A1
(43) Pub. Date: Apr. 17, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventor: Nam Jae LEE, Gyeonggi-do (KR)

(21) Appl. No.: 18/436,030

(22) Filed: Feb. 8, 2024

(30) Foreign Application Priority Data
Oct. 17, 2023 (KR) 10-2023-0139013

(51) Int. Cl. H10B 43/27; H10B 41/27; H10B 41/35; H10B 43/35; H10B 63/00

(52) U.S. Cl. CPC H10B 43/27; H10B 41/27; H10B 41/35; H10B 43/35; H10B 63/34; H10B 63/845

(57) ABSTRACT

A semiconductor device may include a first gate structure including stacked first gate lines; first contact plugs extending through the first gate structure and connected to the first gate lines, respectively; a second gate structure including stacked second gate lines; second contact plugs extending through the second gate structure and connected to the second gate lines, respectively; and a slit structure located between the first gate structure and the second gate structure and including a lower sidewall having a wave shape and an upper sidewall having a straight line shape.

### CROSS-REFERENCE TO RELATED APPLICATION

This application claims priority under 35 U.S.C. § 119 to Korean Patent Application No. 10-2023-0139013 filed on Oct. 17, 2023,which is incorporated herein by reference in its entirety.

### BACKGROUND

### 1. Technical Field

Embodiments of the present disclosure relate generally to an electronic device, and more particularly, to a semiconductor device and a manufacturing method of the semiconductor device.

### 2. Related Art

In semiconductor technology the degree of integration of a semiconductor device refers to how many components or functions can be incorporated into a single integrated circuit (IC) or chip. The degree of integration is mainly determined by the area occupied by a unit memory cell. Higher degree of integration means more powerful and compact electronic devices. However, recently, further improvements in the degree of integration of two-dimensional semiconductor devices which form memory cells in a single layer over a substrate has reached a limit. To overcome this, three-dimensional semiconductor devices which stack memory cells in multiple layers over a substrate have been proposed. Furthermore, in order to improve the operational reliability of such a semiconductor device, various structures and manufacturing methods are developed.

### SUMMARY

The present invention provides a three-dimensional semiconductor device (referred to hereinafter simply as a semiconductor device) exhibiting improved structural and electrical stability and performance characteristics.

In an embodiment of the present disclosure, a semiconductor device may include: a first gate structure including stacked first gate lines; first contact plugs extending through the first gate structure, the first contact plugs being connected to the first gate lines, respectively, wherein at least one first contact plug is connected to each one of the first gate lines; a second gate structure including stacked second gate lines; second contact plugs extending through the second gate structure, the second contact plugs being connected to the second gate lines, respectively, wherein at least one second contact plug is connected to each one of the second contact gates; and a slit structure located between the first gate structure and the second gate structure electrically isolating the first gate structure from the second gate structure, the slit structure including a lower sidewall having a wave shape and an upper sidewall having a straight line shape.

In an embodiment of the present disclosure, a manufacturing method of a semiconductor device may include: forming a first stack including first material layers and second material layers that are alternately stacked; forming holes in the first stack; forming a second stack on the first stack, the second stack including third material layers and fourth material layers that are alternately stacked; forming a trench extending through the second stack and the first stack and connected to the holes; forming a slit by connecting the holes to each other, the slit including a lower sidewall having a wave shape and an upper sidewall having a straight line shape; replacing the first material layers and the third material layers with fifth material layers through the slit; and forming a slit structure in the slit.

In an embodiment of the present disclosure, a manufacturing method of a semiconductor device may include: forming a first stack including first material layers and second material layers that are alternately stacked; forming holes in the first stack; forming a second stack on the first stack, the second stack including third material layers and fourth material layers that are alternately stacked; forming a preliminary trench in the second stack, the preliminary trench having a bottom surface with a stair shape; forming contact holes in the second stack, the contact holes exposing the third material layers; extending some of the contact holes into the first stack; forming a trench connected to the holes by extending the preliminary trench into the first stack; and forming a slit by connecting the holes to each other.

These and other features and advantages of the present invention will become apparent from the following detailed description of specific embodiments in conjunction with the following figures.

### BRIEF DESCRIPTION OF THE DRAWINGS

FIGS. 1A to 1D are diagrams illustrating the structure of a semiconductor device in accordance with an embodiment of the present disclosure.

FIGS. 2A and 2B are diagrams illustrating the structure of a semiconductor device in accordance with an embodiment of the present disclosure.

FIGS. 3A, 4A, 5A, 6A, 7A, 8A, 9A, 10A, 11A, and 12A, FIGS. 3B, 4B, 5B, 6B, 7B, 8B, 9B, 10B, 11B, and 12B, FIGS. 5C, 6C, 7C, 8C, 9C, 10C, 11C, and 12C, FIGS. 5D, 6D, 7D, 8D, 9D, 10D, 11D, and 12D, and FIGS. 7E and 8E are diagrams for describing a manufacturing method of a semiconductor method in accordance with an embodiment of the present disclosure.

### DETAILED DESCRIPTION

Various embodiments of the present disclosure are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

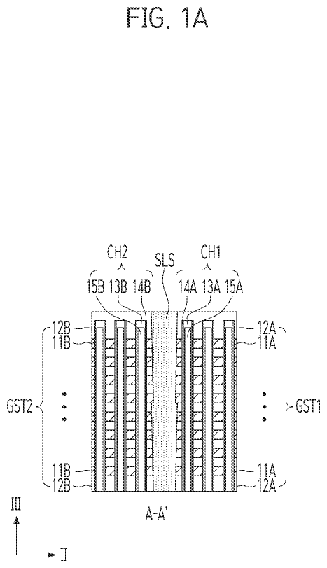

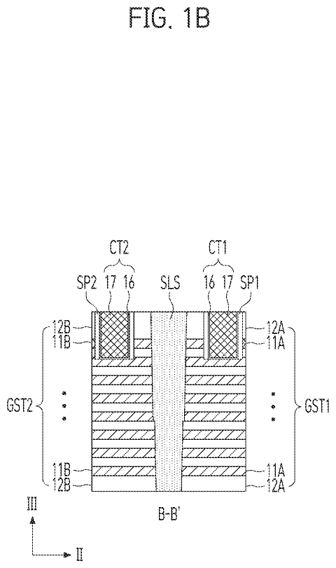

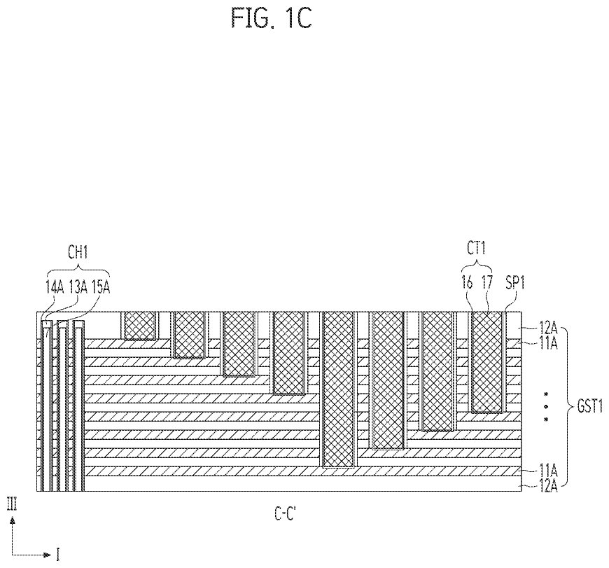

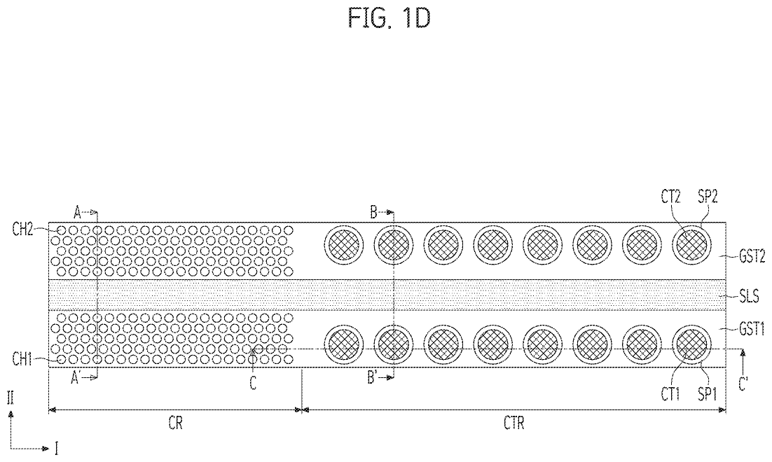

FIGS. 1A to 1D are diagrams illustrating the structure of a semiconductor device in accordance with an embodiment of the present disclosure. FIG. 1A is a cross-sectional view taken along line A-A′ of FIG. 1D, FIG. 1B is a cross-sectional view taken along line B-B′ of FIG. 1D, and FIG. 1C is a cross-sectional view taken along line C-C′ of FIG. 1D.

Referring to FIGS. 1A to 1D, the semiconductor device may include a first gate structure GST1, a second gate structure GST2, first contact plugs CT1, second contact plugs CT2, and a slit structure SLS. The semiconductor device may further include at least one of a first channel structure CH1, a second channel structure CH2, a first insulating spacer SP1, and a second insulating spacer SP2.

The first gate structure GST1 may include stacked first gate lines 11A. The first gate structure GST1 may include the first gate lines 11A and first insulating layers 12A that are alternately stacked. The first gate lines 11A may be word lines, source select lines, or drain select lines.

The first gate structure GST1 may include a cell region CR and a contact region CTR adjacent to each other in a first direction I. The cell region CR may be a region where memory cells are stacked. Here, a portion of the cell region CR may be an end of a memory block. Dummy memory cells may be stacked in the corresponding region. The contact region CTR may be a region where an interconnection structure for transmitting a bias for driving the stacked memory cells is formed. The interconnection structure may include a contact plug, a wiring line, and the like.

The second gate structure GST2 may include stacked second gate lines 11B. The second gate structure GST2 may include the second gate lines 11B and second insulating layers 12B that are alternately stacked. The second gate lines 11B may be word lines, source select lines, or drain select lines. The first gate structure GST1 and the second gate structure GST2 may extend in the first direction I. The first gate structure GST1 and the second gate structure GST2 may be adjacent to each other in a second direction II intersecting the first direction I.

The first channel structure CH1 may extend through the cell region CR of the first gate structure GST1. As an example, the first channel structure CH1 may extend in a third direction III. The third direction III may be perpendicular to a plane defined by the first and second directions I and II. The first channel structure CH1 may include at least one of a first channel layer 13A, a first memory layer 14A, and a first insulating core 15A. The first memory layer 14A may include at least one of a tunneling layer, a data storage layer, and a blocking layer. The data storage layer may include a floating gate, polysilicon, a charge trap material, nitride, a variable resistance material, or the like.

The second channel structure CH2 may extend through the second gate structure GST2. The second channel structure CH2 may extend in the third direction III. The second channel structure CH2 may include at least one of a second channel layer 13B, a second memory layer 14B, and a second insulating core 15B. The second memory layer 14B may include at least one of a tunneling layer, a data storage layer, and a blocking layer. The data storage layer may include a floating gate, polysilicon, a charge trap material, nitride, a variable resistance material, or the like.

The first contact plugs CT1 may extend through the contact region CTR of the first gate structure GST1, and may be connected to the first gate lines 11A, respectively. The first contact plugs CT1 may extend into the first gate structure GST1 at different depths to connect at different first gate lines 11A. The first contact plugs CT1 may each include a barrier layer 16 and a gap-fill metal layer 17. The first insulating spacer SP1 may surround sidewalls of the first contact plug CT1.

The second contact plugs CT2 may extend through the second gate structure GST2, and may be connected to the second gate lines 11B, respectively. The second contact plugs C21 may extend into the second gate structure GST2 at different depths. The second contact plugs CT2 may each include a barrier layer 16 and a gap-fill metal layer 17. The second insulating spacer SP2 may surround sidewalls of the second contact plug CT2.

The slit structure SLS may be located between the first gate structure GST1 and the second gate structure GST2. The slit structure SLS may separate the first gate structure GST1 from the second gate structure GST2 and keep them electrically isolated. The slit structure SLS may include at least one of an insulating material, a semiconductor material, and a conductive material. As an example, the slit structure SLS may include a gap-fill insulating layer made of oxide, nitride, or the like. As an example, the slit structure SLS may include a gap-fill semiconductor layer made of silicon, germanium, or the like. As an example, the slit structure SLS may include a source contact structure including polysilicon, metal, or the like.

According to the structure described above, the first and second contact plugs CT1 and CT2 may extend through the first gate structure GST1 and the second gate structure GST2, respectively. Accordingly, the first gate lines 11A and the second gate lines 11B may be connected to the first contact plugs CT1 and the second contact plugs CT2, respectively, without a stair structure.

In addition, in the plane defined by the first direction I and the second direction II, the slit structure SLS may extend along the first direction I. The first gate structure GST1 and the second gate structure GST2 may be electrically separated from each other by the slit structure SLS.

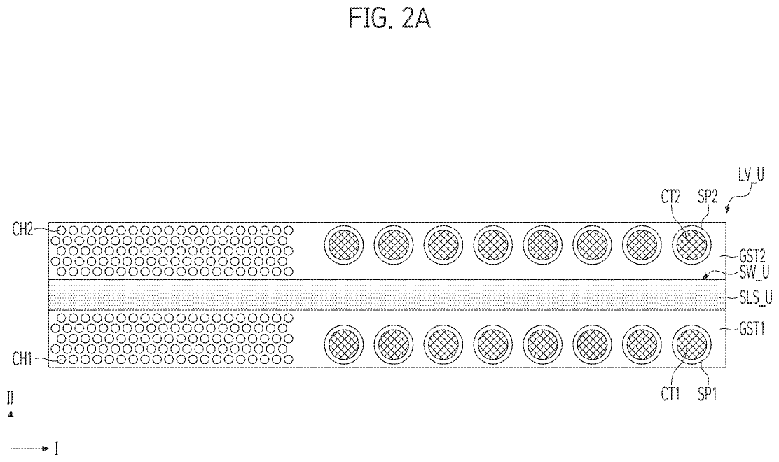

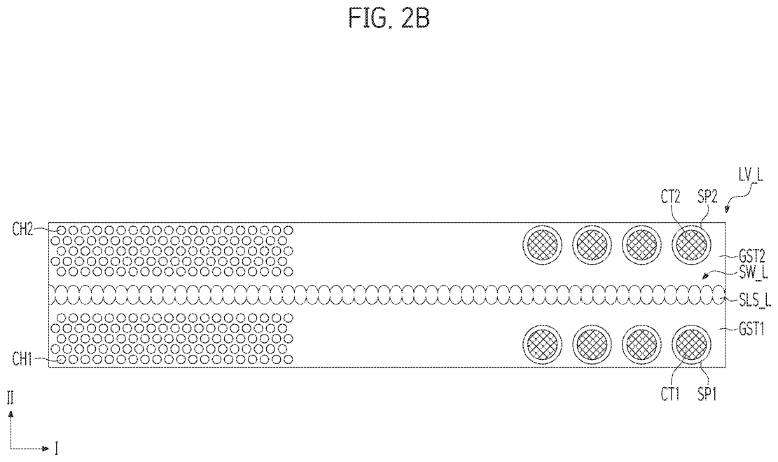

FIGS. 2A and 2B are diagrams illustrating the structure of a semiconductor device in accordance with an embodiment of the present disclosure. FIG. 2A is a plan view at an upper level LV_U of a gate structure, and FIG. 2B is a plan view at a lower level LV_L of the gate structure. Hereinafter, content overlapping with the previously described content may be omitted.

Referring to FIGS. 2A and 2B, the semiconductor device may include at least one of a first gate structure GST1, a second gate structure GST2, first contact plugs CT1, second contact plugs CT2, a slit structure SLS, a first channel structure CH1, a second channel structure CH2, a first insulating spacer SP1, and a second insulating spacer SP2.

The slit structure SLS may be located between the first and second gate structures GST1 and GST2 and may electrically isolate the two gate structures. The slit structure SLS may include an upper portion SLS_U and a lower portion SLS_L. The slit structure SLS may have a structure in which the upper portion SLS_U and the lower portion SLS_L are connected to each other.

The slit structure SLS may include a lower sidewall SW_L and an upper sidewall SW_U that have different shapes. In a plan view, the lower sidewall SW_L may have a wave shape and may extend in the first direction I. As an example, the lower sidewall SW_L may have a shape in which convex portions and concave portions are alternately arranged along the first direction. In a plan view, the upper sidewall SW_U may have a straight line shape, and may extend in the first direction I.

According to the structure described above, the upper portion SLS_U and the lower portion SLS_L of the slit structure SLS may have different shapes. In a plan view, the upper sidewall SW_U may extend in the straight line shape, and the lower sidewall SW_L may extend in the wave shape.

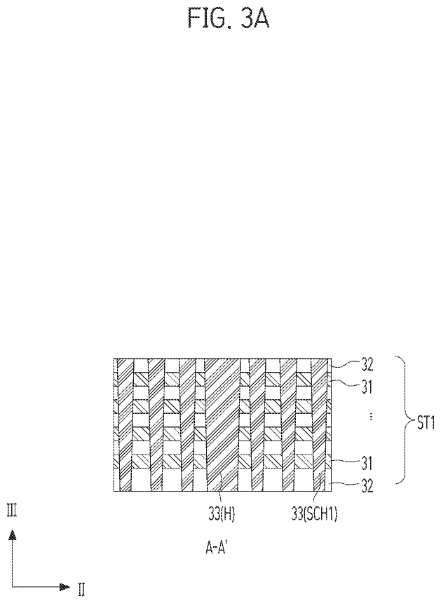

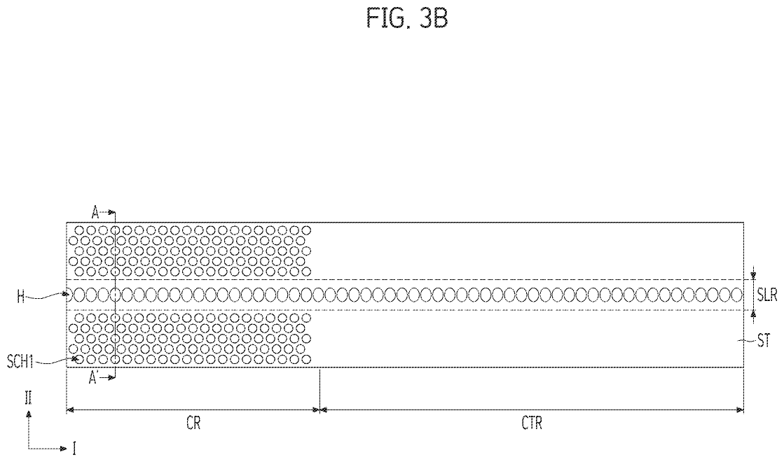

FIGS. 3A, 4A, 5A, 6A, 7A, 8A, 9A, 10A, 11A, and 12A, FIGS. 3B, 4B, 5B, 6B, 7B, 8B, 9B, 10B, 11B, and 12B, FIGS. 5C, 6C, 7C, 8C, 9C, 10C, 11C, and 12C, FIGS. 5D, 6D, 7D, 8D, 9D, 10D, 11D, and 12D, and FIGS. 7E and 8E are diagrams for describing a manufacturing method of a semiconductor method in accordance with an embodiment of the present disclosure. Hereinafter, content overlapping with the previously described content may be omitted.

Referring to FIGS. 3A and 3B, a first stack ST1 may be formed. The first stack ST1 may include first material layers 31 and second material layers 32 that are alternately stacked. The first material layers 31 may be used to form gate lines, and the second material layers 32 may be used to insulate the stacked gate lines from each other. As an example, the first material layers 31 may each include a sacrificial material such as nitride or a conductive material such as polysilicon, tungsten, or molybdenum. The second material layers 32 may each include an insulating material such as oxide, nitride, or a void.

The first stack ST1 may include a cell region CR and a contact region CTR. The cell region CR may be a region where memory cells are to be stacked. The contact region CTR may be a region where an interconnection structure for transmitting a bias for driving the stacked memory cells is to be formed. The interconnection structure may include a contact plug, a wiring line, and the like.

Subsequently, holes H may be formed in the first stack ST1. The holes H may be formed in a slit region SLR where a slit is to be formed. The slit region SLR may be located in the cell region CR, and may extend to the contact region CTR. The slit region SLR may extend along the first direction I. The holes H may extend through the first stack ST1, and may extend in the third direction III. In a plan view, the holes H may each have a circular shape, an elliptical shape, a polygonal shape, or the like.

First sub-channel holes SCH1 may be formed in the first stack ST1. The first sub-channel holes SCH1 may be formed in the cell region CR. When the holes H are formed, the first sub-channel holes SCH1 may also be formed at the same time. The holes H may have a greater size than or substantially the same size as the first sub-channel holes SCH1.

Subsequently, first sacrificial layers 33 may be formed in the holes H and the first sub-channel holes SCH1. The first sacrificial layers 33 may each include a material having a high etching selectivity with respect to the first material layers 31 and the second material layers 32.

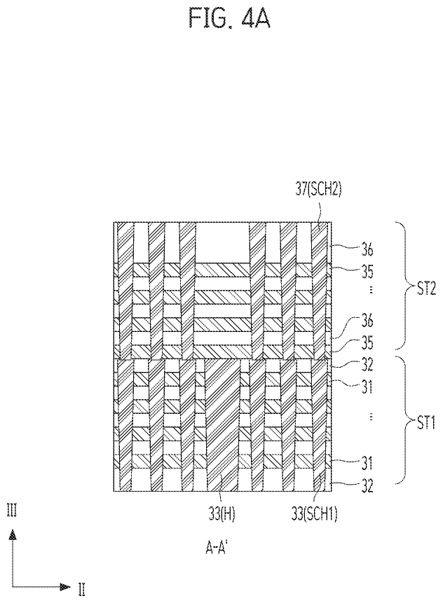

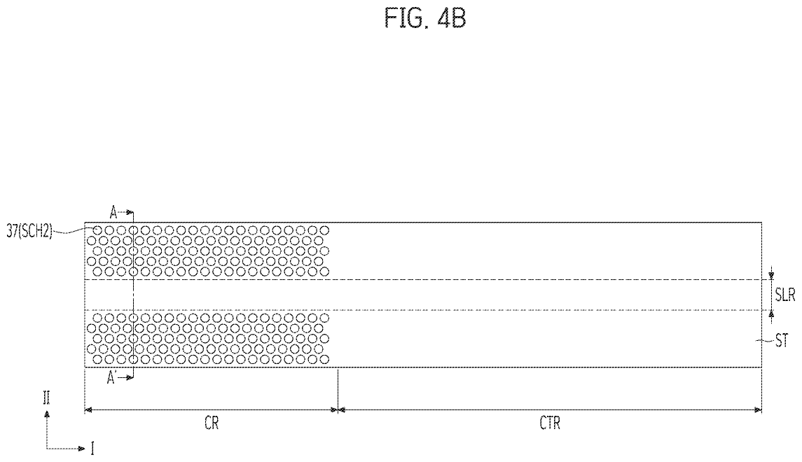

Referring to FIGS. 4A and 4B, a second stack ST2 may be formed. The second stack ST2 may be formed to overlap with the first stack ST1. The second stack ST2 may include third material layers 35 and fourth material layers 36 that are alternately stacked. The third material layers 35 may be used to form gate lines, and the fourth material layers 36 may be used to insulate the stacked gate lines from each other. As an example, the third material layers 35 may each include a sacrificial material such as nitride or a conductive material such as polysilicon, tungsten, or molybdenum. The fourth material layers 36 may each include an insulating material such as oxide, nitride, or void.

Subsequently, second sub-channel holes SCH2 may be formed in the second stack ST2. The second sub-channel holes SCH2 may be connected to corresponding first sub-channel holes SCH1, respectively. The second sub-channel holes SCH2 may not be formed in the slit region SLR.

Subsequently, second sacrificial layers 37 may be formed in the second sub-channel holes SCH2. The second sacrificial layers 37 may each include a material having a high etching selectivity with respect to the third material layers 35 and the fourth material layers 36.

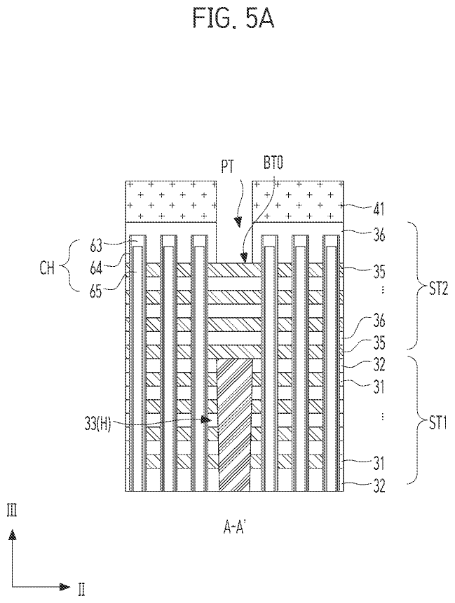

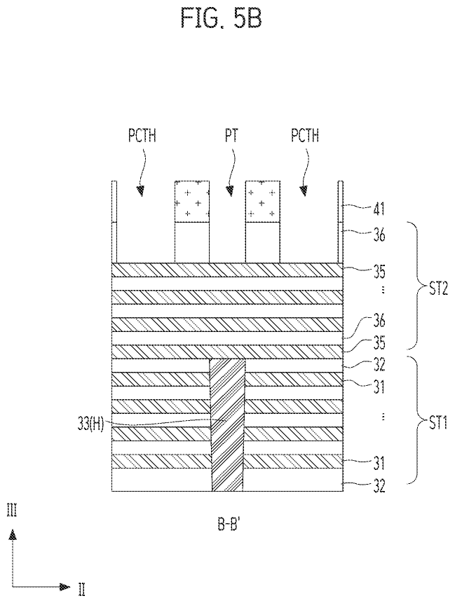

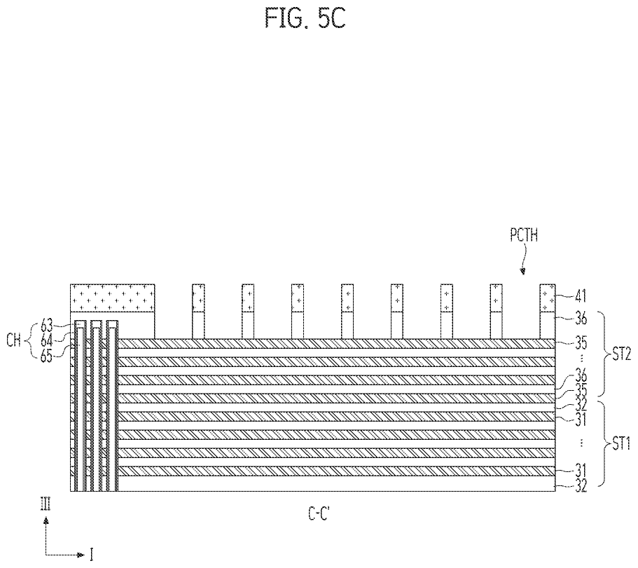

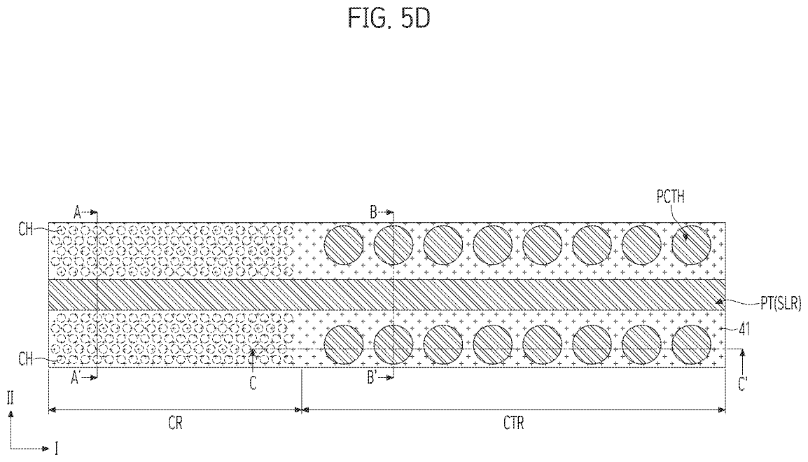

Referring to FIGS. 5A to 5D, channel structures CH may be formed. First, the first sub-channel holes SCH1 and the second sub-channel holes SCH2 may be reopened by removing the second sacrificial layers 37 and the first sacrificial layers 33. Subsequently, the channel structures CH may be formed in the reopened first sub-channel holes SCH1 and second sub-channel holes SCH2. The channel structure CH may include at least one of a channel layer 63, a memory layer 64, and an insulating core 65. Subsequently, a fourth material layer 36 may be additionally formed on the second stack ST2.

Subsequently, a hard mask pattern 41 may be formed on the second stack ST2. As an example, the hard mask pattern 41 may be formed by forming a hard mask layer and then etching the hard mask layer using a photoresist pattern as an etching barrier. The hard mask pattern 41 may cover the channel structures CH, and may include openings exposing regions where contact plugs are to be formed and the slit region SLR. The hard mask pattern 41 may include polysilicon.

Subsequently, the second stack ST2 may be etched using the hard mask pattern 41 as an etching barrier. Through this, a preliminary trench PT may be formed in the slit region SLR. The preliminary trench PT may have a bottom surface BTO exposing the uppermost third material layer 35. Preliminary contact holes PCTH may be formed in a region where contact plugs are to be formed. When the preliminary trench PT is formed, the preliminary contact holes PCTH may be formed at the same time. The preliminary contact holes PCTH and the preliminary trench PT may each have a depth enough to expose the uppermost third material layer 35.

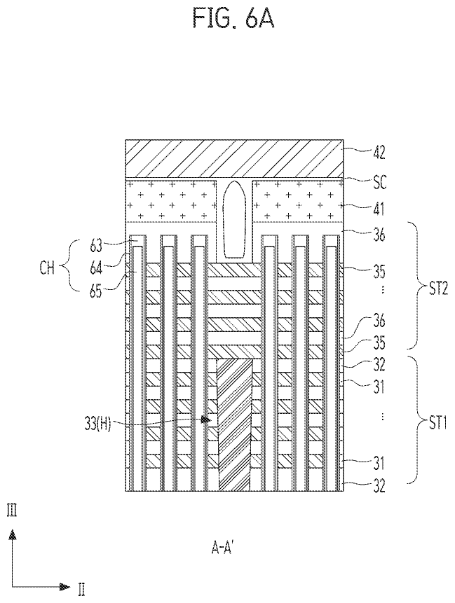

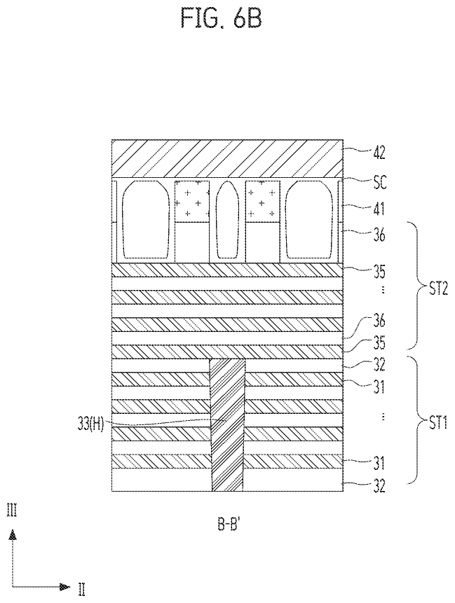

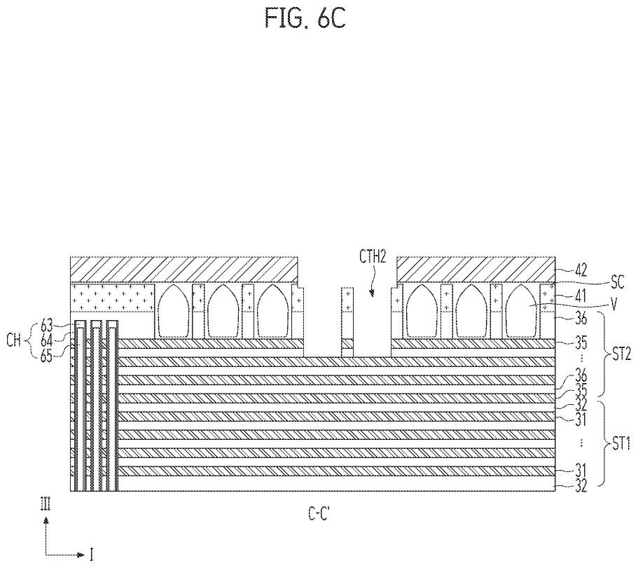

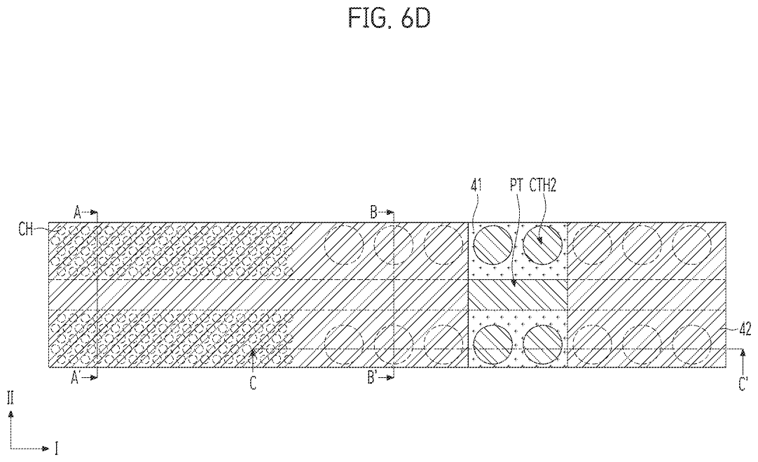

Referring to FIGS. 6A to 6D, a sacrificial layer SC may be formed on the hard mask pattern 41. The sacrificial layer SC may be formed to at least partially fill the preliminary contact holes PCTH and the preliminary trench PT. The sacrificial layer SC may include a material having a high etching selectivity with respect to the hard mask pattern 41. As an example, the sacrificial layer SC may include amorphous silicon. When the sacrificial layer SC is formed, voids V may be formed in the preliminary contact holes PCTH and the preliminary trench PT.

Subsequently, a first mask pattern 42 may be formed on the sacrificial layer SC. The first mask pattern 42 may include an opening exposing some of the preliminary contact holes PCTH. The first mask pattern 42 may also expose a portion of the preliminary trench PT. A portion of the preliminary trench PT located between the exposed preliminary contact holes PCTH may be exposed.

Subsequently, the sacrificial layer SC and the second stack ST2 may be etched using the first mask pattern 42 and the hard mask pattern 41 as etching barriers. Through this, the exposed preliminary contact holes PCTH may extend into the second stack ST2, to form the second contact holes CTH2 which expose the third material layer 35. The exposed portion of the preliminary trench PT may extend into the second stack ST, and a bottom surface with a step shape may be formed.

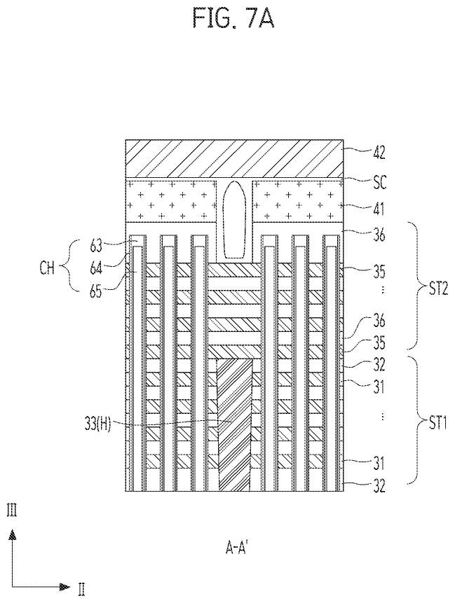

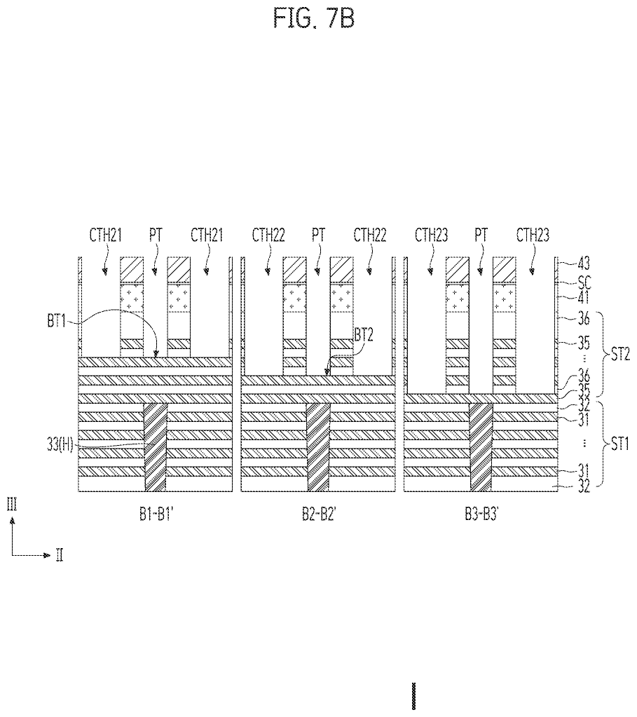

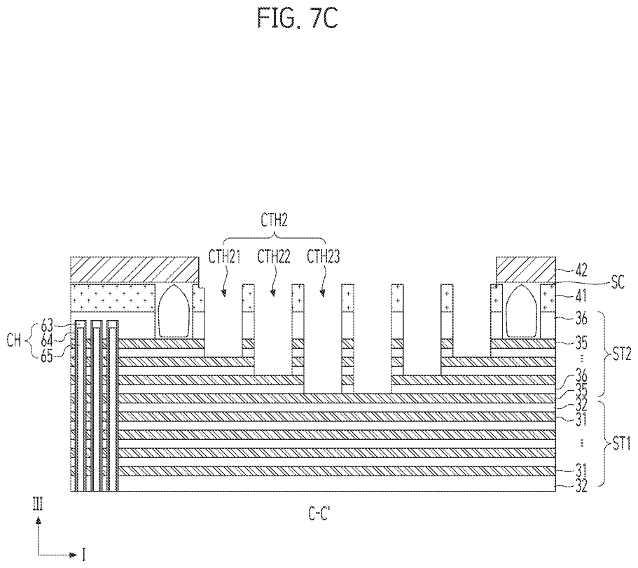

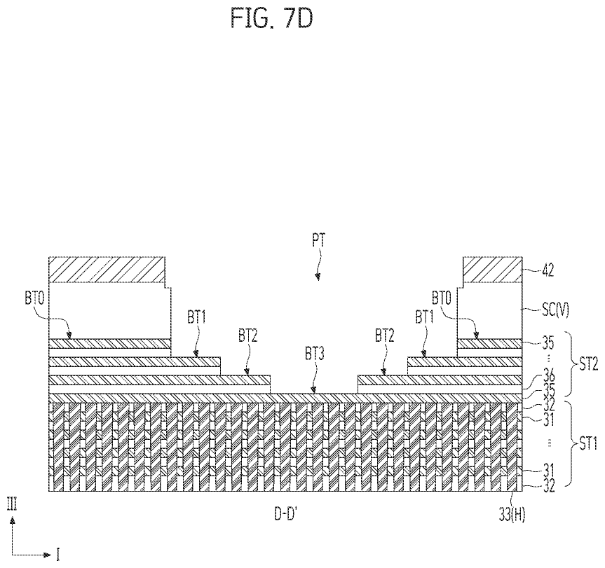

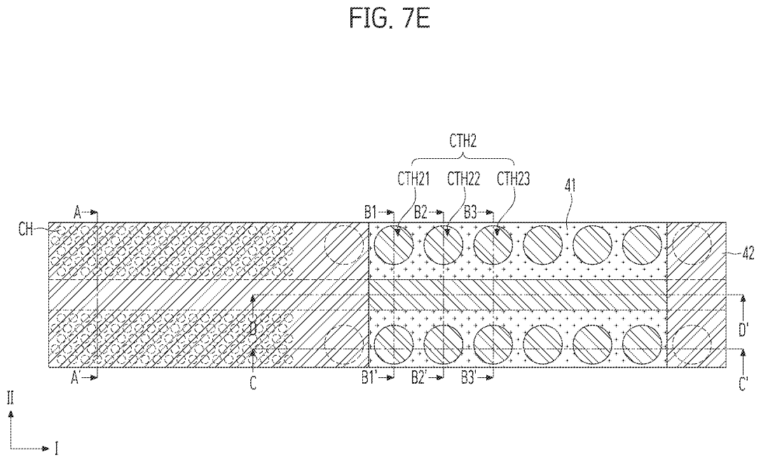

Referring to FIGS. 7A to 7E, the opening of the first mask pattern 42 may be expanded. As an example, the opening may be expanded by reducing the first mask pattern 42 through an etching process. Through this, the number of exposed preliminary contact holes PCTH may be increased, and the exposed portion of the preliminary trench PT may be increased as shown in FIG. 7B.

Subsequently, the second stack ST2 may be etched using the first mask pattern 42 and the hard mask pattern 41 as etching barriers. Through this, second contact holes CTH2 exposing the third material layers 35 may be formed by extending the preliminary contact holes PCTH into the second stack ST2. In addition, the previously formed second contact holes CTH2 may be further extended into the second stack ST2. A newly exposed portion of the preliminary trench may be etched, and the bottom surface with the step shape may be extended into the second stack ST2.

Subsequently, a reduction of the first mask pattern 42 and an etching process may be repeatedly performed. The second contact hole CTH2 formed earlier may be etched a large number of times and at a greater depth than a second contact hole CTH2 formed later. Through this, the second contact holes CTH2 may be formed to extend at various depths, and expose different third material layers 35, respectively. Likewise, an earlier exposed portion of the preliminary trench PT may be etched a large number of times and at a greater depth than a later exposed portion of the preliminary trench PT. Through this, the preliminary trench PT may be extended at various depths depending on portions, and the preliminary trench PT having the bottom surface with the stair shape (also referred to as a step or stepped shape) may be formed. When the preliminary trench PT is formed, the second contact holes CTH2 may be formed. Subsequently, the first mask pattern 42 and the sacrificial layer SC may be removed.

The preliminary trench PT may have the bottom surface with the stair shape in a portion thereof. As an example, a portion of the preliminary trench PT located between the channel structures CH may maintain a depth of the bottom surface BTO initially formed, and might not have the bottom surface with the stair shape. Portions of the preliminary trench PT located between the second contact holes CTH2 may be etched together with the second contact holes CTH2 when the second contact holes CTH2 are formed. Accordingly, each portion of the preliminary trench PT may have the same depth as the second contact holes CTH2 adjacent in the second direction II. A third bottom surface BT3 located between second contact holes CTH23 having a relatively deep depth may be located at a lower level than a second bottom surface BT2 located between second contact holes CTH22. A first bottom surface BT1 located between second contact holes CTH21 having a relatively shallow depth may be located at a higher level than the second bottom surface BT2.

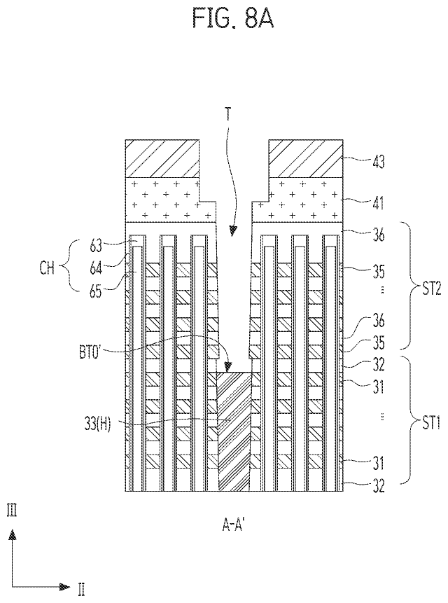

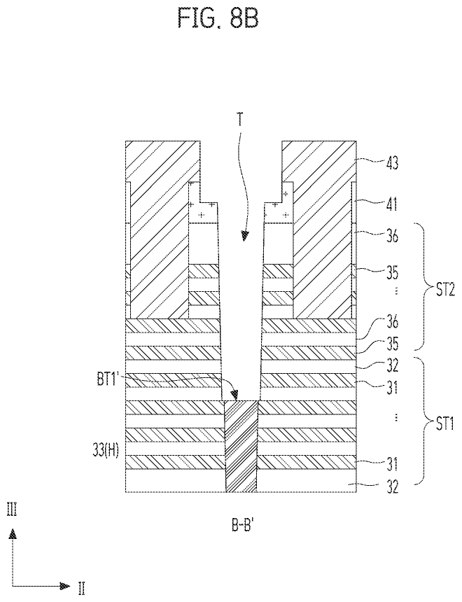

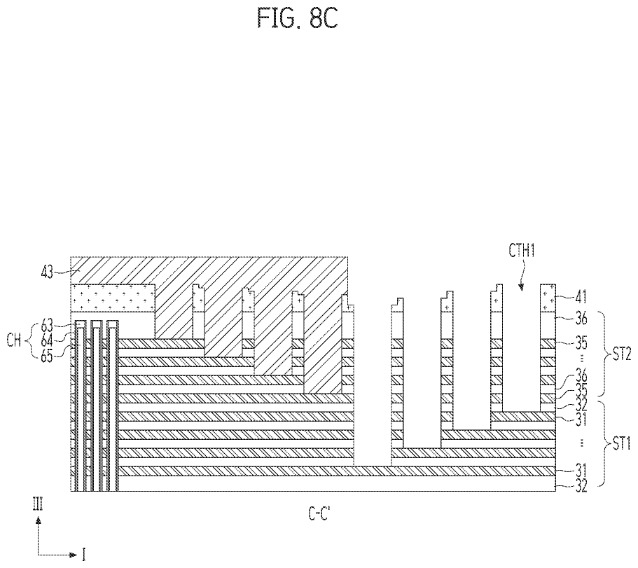

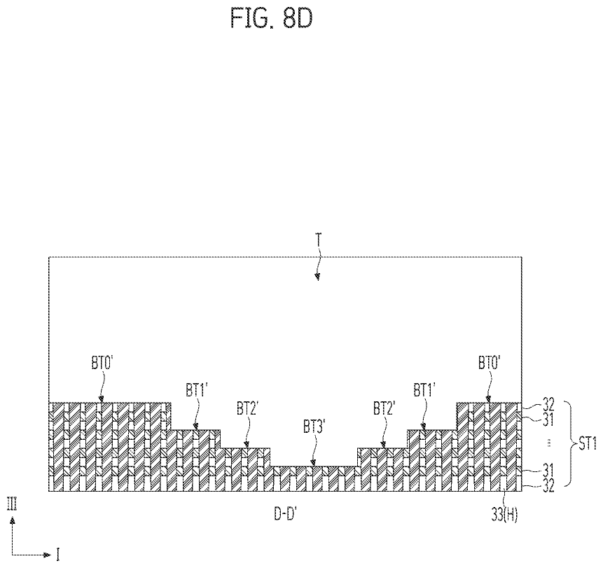

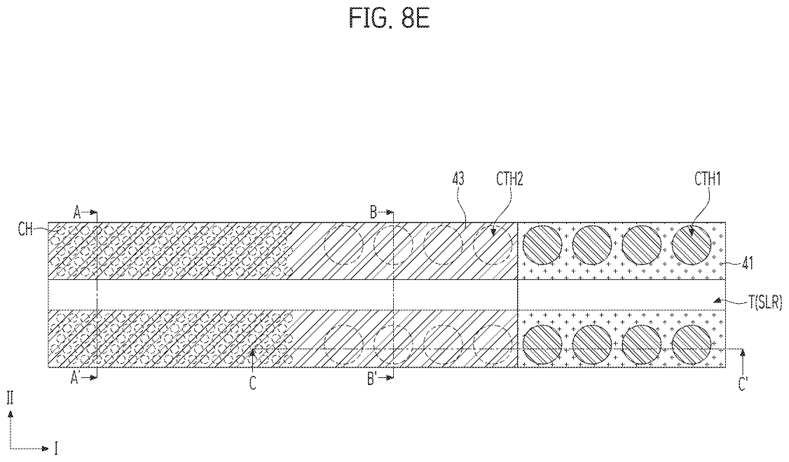

Referring to FIGS. 8A to 8E, a second mask pattern 43 may be formed on the hard mask pattern 41. The second mask pattern 43 may cover the channel structures CH, and may expose the slit region SLR. The second mask pattern 43 may expose only some of the second contact holes CTH2, and cover the remaining second contact holes CTH2.

Subsequently, the second stack ST2 and the first stack ST1 may be etched using the hard mask pattern 41 and the second mask pattern 43 as etching barriers. Through this, the exposed second contact holes

CTH2 may be extended into the first stack ST1, and first contact holes CTH1 respectively exposing the first material layers 31 may be formed. Through this, the preliminary trench PT may be extended into the first stack ST1, and a trench T connected to the holes H may be formed. When the trench T is formed, the first contact holes CTH1 may be formed.

As an example, the first stack ST1 may include n first material layers 31, and the second stack ST2 may include n third material layers 35. In such a case, by repeatedly performing an etching process using the first mask pattern 42, 2n second contact holes CTH2 may be formed.

In addition, by etching n-layer first and third material layers 31 and 35 using the second mask pattern 43, n second contact holes CTH2 of the 2n second contact holes CTH2 may be extended into the first stack ST1, and n first contact holes CTH1 may be formed.

The preliminary trench PT may be formed when the 2n second contact holes CTH2 are formed, and the trench T may be formed when the n first contact holes CTH1 are formed. By etching the n-layer first and third material layers 31 and 35 using the second mask pattern 43, the preliminary trench PT may be extended into the first stack ST1, and the trench T connected to the holes H may be formed. A bottom surface of the trench T may have a stair shape in which the bottom surface of the preliminary trench PT is transferred. The bottom surfaces BTO to BT3 of the preliminary trench PT may be transferred into the first stack ST1 to form bottom surfaces BTO′ to BT3′ of the trench T.

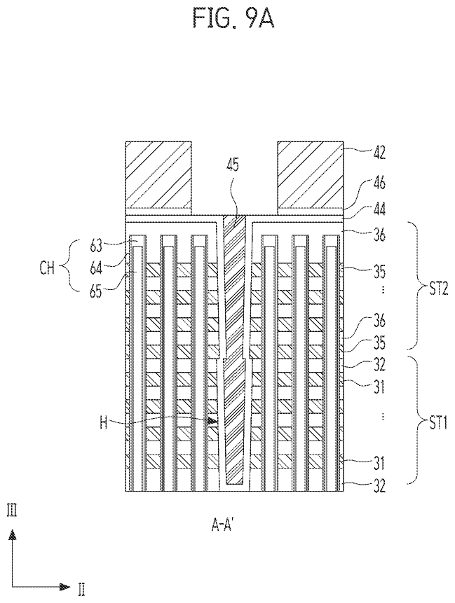

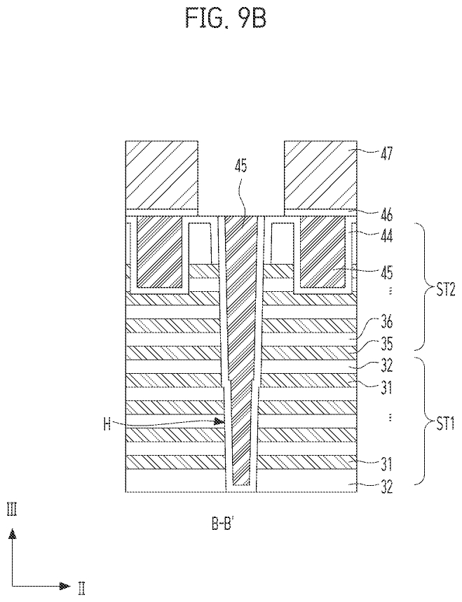

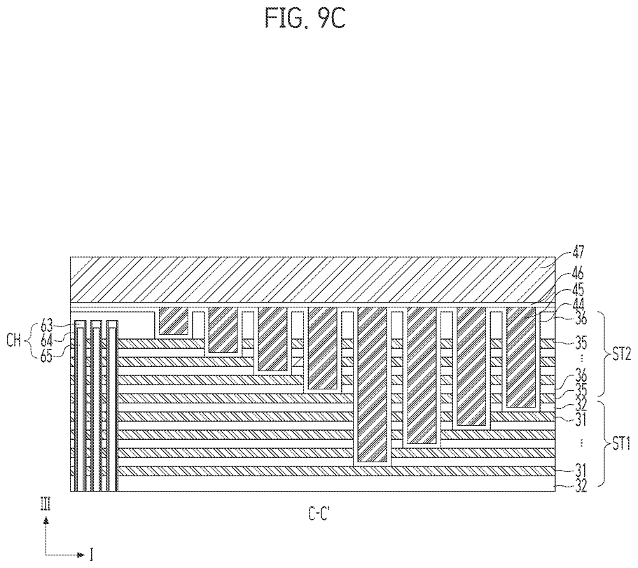

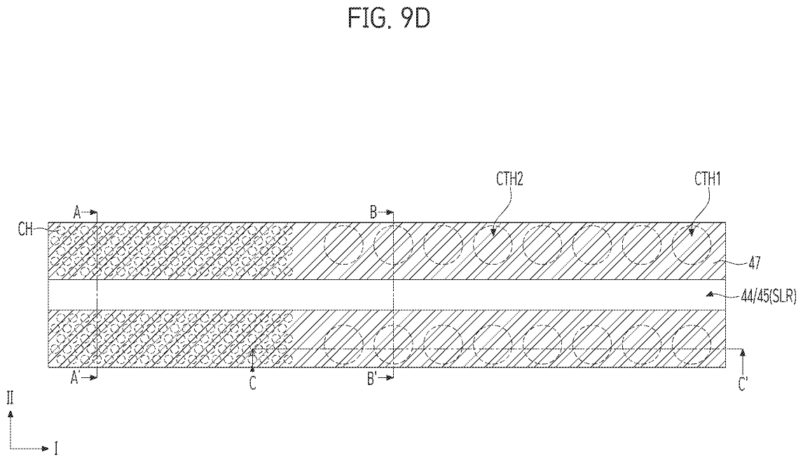

Referring to FIGS. 9A to 9D, the first sacrificial layers 33 in the holes H may be removed through the trench T. The second mask pattern 43 and the hard mask pattern 41 may be removed.

Subsequently, a first liner layer 44 may be formed in the first contact holes CTH1, the second contact holes CTH2, the holes H, and the trench T. The first liner layer 44 may be formed along profiles of the first contact holes CTH1, the second contact holes CTH2, the holes H, and the trench T. The first liner layer 44 may include a material having a high etching selectivity with respect to the first material layers 31 and the third material layers 35. As an example, the first liner layer 44 may include an oxide.

Subsequently, a sacrificial layer 45 may be formed in the first contact holes CTH1, the second contact holes CTH2, the holes H, and the trench T. Subsequently, a second liner layer 46 may be formed on the sacrificial layer 45. The sacrificial layer 45 may include a material having a high etching selectivity with respect to the first liner layer 44 and the second liner layer 46. As an example, the sacrificial layer 45 may include polysilicon, and the first liner layer 44 and the second liner layer 46 may each include an oxide.

Subsequently, a third mask pattern 47 exposing the slit region SLR may be formed. The third mask pattern 47 may cover the channel structures CH, the first contact holes CTH1, and the second contact holes CTH2, and may expose the trench T.

Subsequently, the second liner layer 46 may be etched using the third mask pattern 47 as an etching barrier. Through this, the sacrificial layer 45 and the first liner layer 44 formed in the trench T may be exposed.

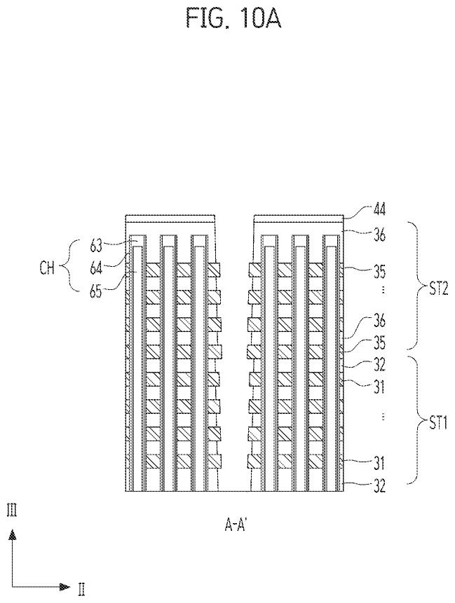

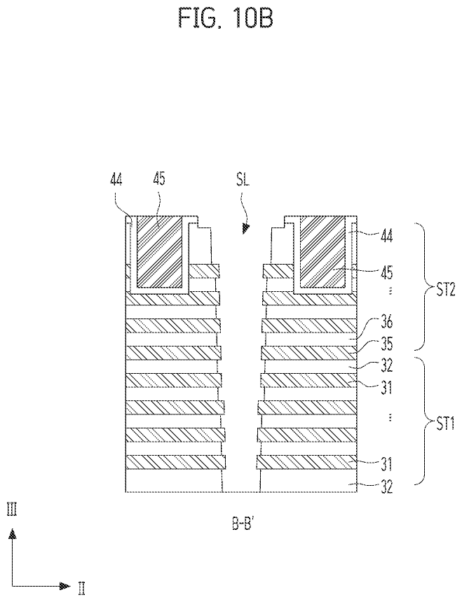

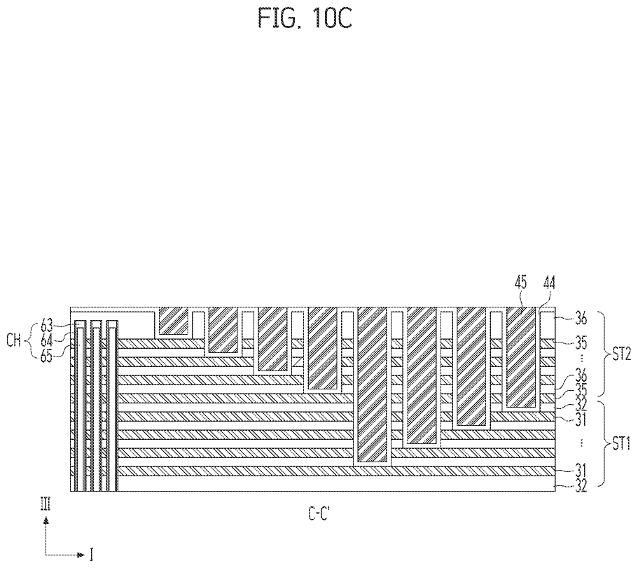

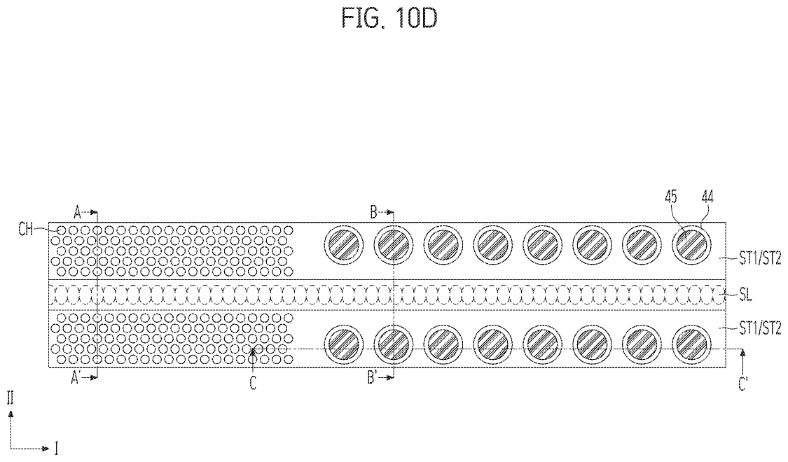

Referring to FIGS. 10A to 10D, the sacrificial layer 45 and the first liner layer 44 exposed by the third mask pattern 47 may be removed. As an example, the sacrificial layer 45 and the first liner layer 44 in the trench T and the holes H may be selectively etched using a dry cleaning process. Through this, the trench T and the holes H may be reopened.

Subsequently, a slit SL may be formed by connecting the holes H to each other. The second material layers 32 and the fourth material layers 36 exposed through the trench T and the holes H may be selectively etched so that the holes H are connected to each other. Through this, the holes H may be expanded, and adjacent holes H may be connected to each other. The holes H may be connected to each other in a wave shape. The holes H may be connected to each other to form a lower portion of the slit SL, and a lower sidewall of the slit SL may have a wave shape in a plan view. The trench T may be expanded to form an upper portion of the slit SL, and an upper sidewall of the slit SL may have a straight line shape in a plan view.

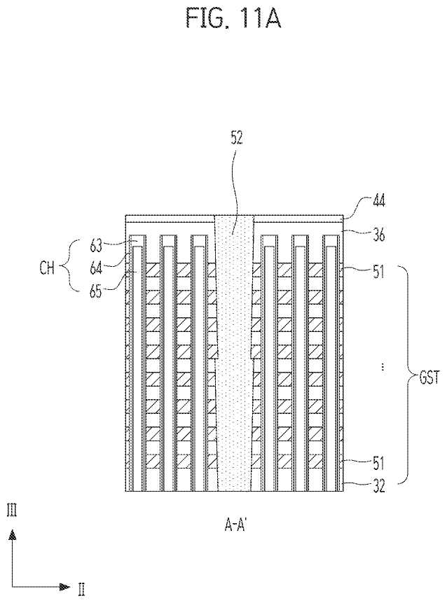

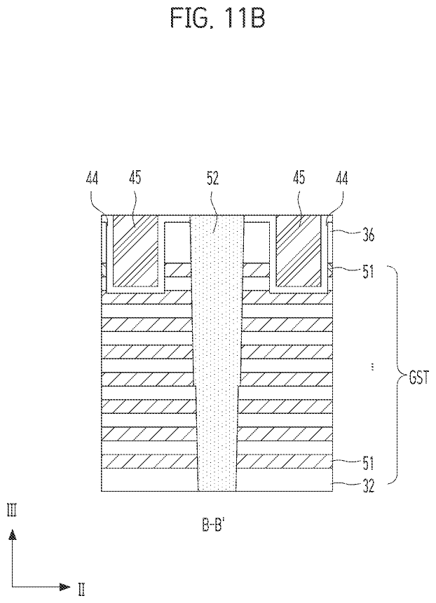

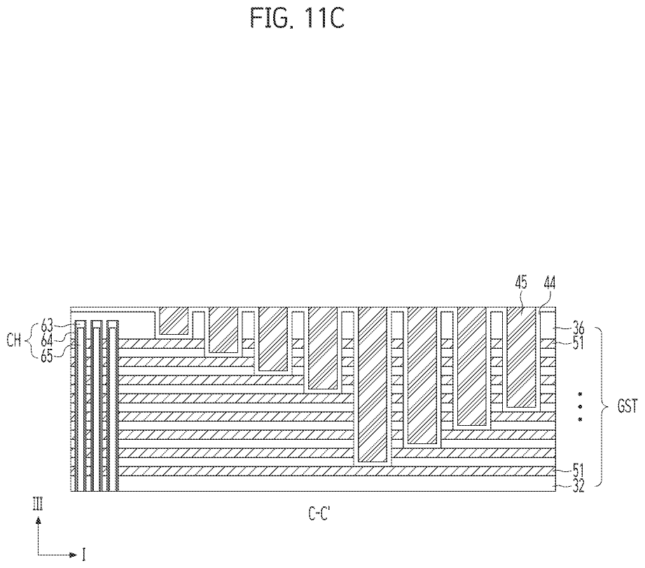

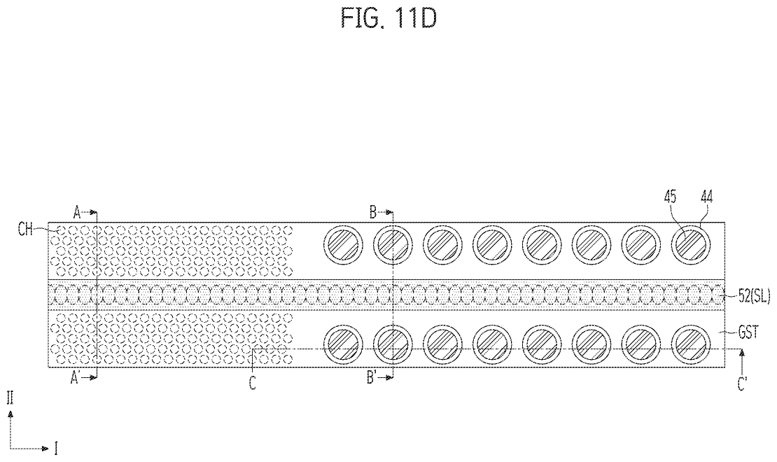

Referring to FIGS. 11A to 11D, the first material layers 31 and the third material layers 35 may be replaced with fifth material layers 51 through the slit SL. As an example, the first material layers 31 and the third material layers 35 may be removed through the slit SL. Subsequently, the fifth material layers 51 may be formed in regions where the first material layers 31 and the third material layers 35 are removed. Before the fifth material layers 51 are formed, a blocking layer may be additionally formed. Here, the fifth material layers 51 may be gate lines, and may each include metal such as tungsten or molybdenum. Through this, a gate structure GST including the stacked fifth material layers 51 may be formed. For reference, a replacement process may be omitted when the first material layers 31 and the third material layers 35 each include a conductive material. In such a case, the first material layers 31 and the third material layers 35 may be gate lines, and the first stack ST1 and the second stack ST2 may be the gate structure GST.

Subsequently, a slit structure 52 may be formed in the slit SL. The slit structure 52 may include at least one of an insulating material, a semiconductor material, and a conductive material. As an example, the slit structure 52 may include a gap-fill insulating layer made of oxide, nitride, or the like. The slit structure 52 may include a gap-fill semiconductor layer made of silicon, germanium, or the like. The slit structure 52 may include a source contact structure having conductivity and an insulating spacer surrounding sidewalls of the source contact structure.

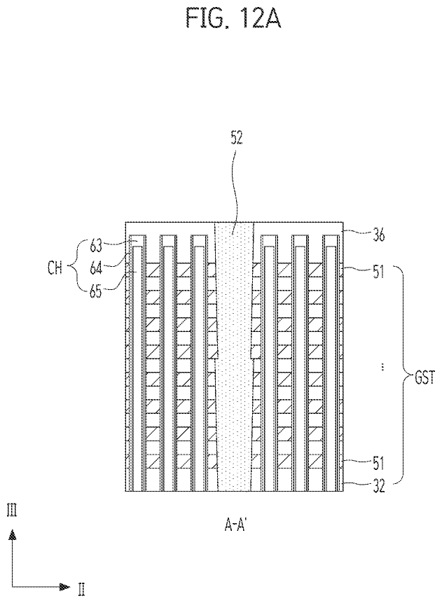

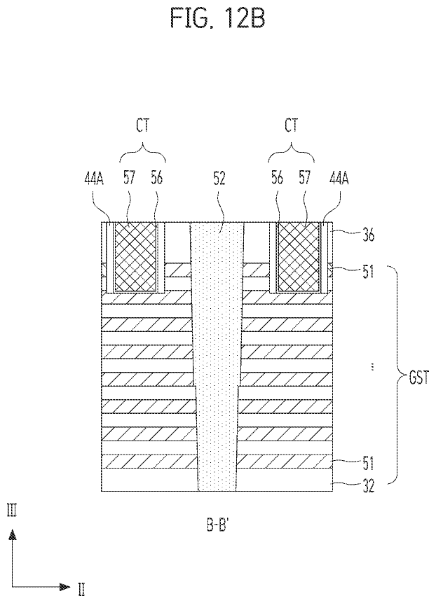

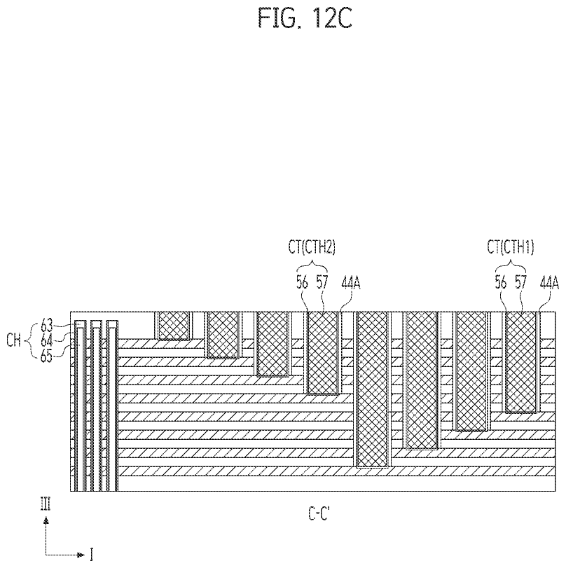

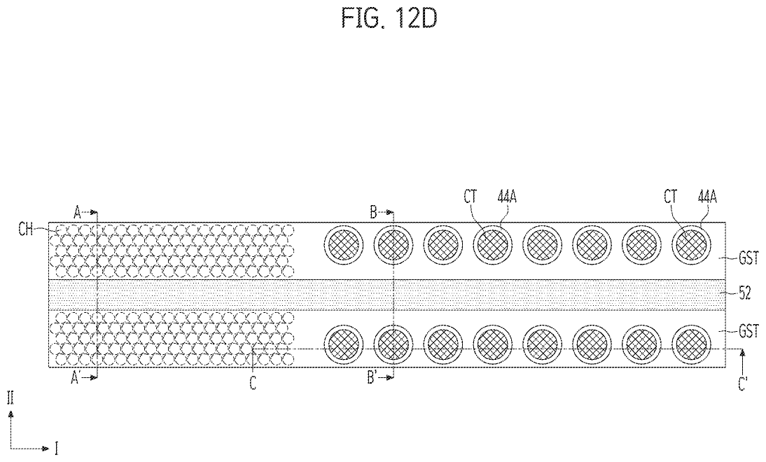

Referring to FIGS. 12A to 12D, the sacrificial layer 45 may be removed. Subsequently, insulating spacers 44A may be formed by etching the first liner layer 44. Subsequently, contact plugs CT may be formed in the first contact holes CTH1 and the second contact holes CTH2. As an example, a barrier layer 56 may be formed in the first contact holes CTH1 and the second contact holes CTH2, and a gap-fill metal layer 57 may be formed in the barrier layer 56. Through this, the contact plugs CT extending through the gate structure GST and respectively connected to the fifth material layers 51 may be formed.

According to the manufacturing method described above, when the first sub-channel hole SCH1 is formed, the holes H may be formed. When the second contact holes CTH2 and the first contact holes CTH1 are formed, the trench T may be formed. Accordingly, the slit SL may be formed using a sub-channel hole forming process and a contact hole forming process.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A semiconductor device comprising:
a first gate structure including stacked first gate lines;
first contact plugs extending through the first gate structure, the first contact plugs being connected to the first gate lines, respectively, wherein at least one first contact plug is connected to each one of the first gate lines;
a second gate structure including stacked second gate lines;
second contact plugs extending through the second gate structure, the second contact plugs being connected to the second gate lines, respectively, wherein at least one second contact plug is connected to each one of the second contact gates; and
a slit structure located between the first gate structure and the second gate structure electrically isolating the first gate structure from the second gate structure, the slit structure including a lower sidewall having a wave shape and an upper sidewall having a straight line shape.

2. The semiconductor device of claim 1, wherein the slit structure extends in a first direction, and
wherein the first gate structure and the second gate structure are adjacent to each other in a second direction intersecting the first direction.

3. The semiconductor device of claim 2, wherein the lower sidewall has a shape in which concave portions and convex portions are alternately arranged along the first direction.

4. The semiconductor device of claim 1, wherein the first contact plugs extend into the first gate structure at different depths.

5. The semiconductor device of claim 1, wherein the second contact plugs extend into the second gate structure at different depths.

6. The semiconductor device of claim 1, further comprising:
first insulating spacers surrounding sidewalls of the first contact plugs, respectively; and
second insulating spacers surrounding sidewalls of the second contact plugs, respectively.

7. The semiconductor device of claim 1, further comprising:
a first channel structure extending through the first gate structure; and
a second channel structure extending through the second gate structure.

8. A manufacturing method of a semiconductor device, the manufacturing method comprising:
forming a first stack including first material layers and second material layers that are alternately stacked;
forming holes in the first stack;
forming a second stack on the first stack, the second stack including third material layers and fourth material layers that are alternately stacked;
forming a trench extending through the second stack and the first stack and connected to the holes;
forming a slit by connecting the holes to each other, the slit including a lower sidewall having a wave shape and an upper sidewall having a straight line shape;
replacing the first material layers and the third material layers with fifth material layers through the slit; and
forming a slit structure in the slit.

9. The manufacturing method of claim 8, wherein a first sub-channel hole is formed in the first stack when the holes are formed.

10. The manufacturing method of claim 9, further comprising forming a second sub-channel hole in the second stack, the second sub-channel hole being connected to the first sub-channel hole.

11. The manufacturing method of claim 8, wherein the forming of the trench comprises:
forming a preliminary trench in the second stack, the preliminary trench having a bottom surface with a stair shape; and
forming the trench by extending the preliminary trench into the first stack.

12. The manufacturing method of claim 11, wherein second contact holes exposing the third material layers are formed in the second stack when the preliminary trench is formed.

13. The manufacturing method of claim 12, wherein first contact holes exposing the first material layers are formed by extending some of the second contact holes into the first stack when the trench is formed.

14. The manufacturing method of claim 13, further comprising forming contact plugs in the first contact holes and the second contact holes.

15. The manufacturing method of claim 8, wherein in the forming of the slit, the second material layers and the fourth material layers exposed through the holes and the trench are etched so that the holes are connected to each other.

16. A manufacturing method of a semiconductor device, the manufacturing method comprising:
forming a first stack including first material layers and second material layers that are alternately stacked;
forming holes in the first stack;
forming a second stack on the first stack, the second stack including third material layers and fourth material layers that are alternately stacked;
forming a preliminary trench in the second stack, the preliminary trench having a bottom surface with a stair shape;
forming contact holes in the second stack, the contact holes exposing the third material layers;
extending some of the contact holes into the first stack;
forming a trench connected to the holes by extending the preliminary trench into the first stack; and
forming a slit by connecting the holes to each other.

17. The manufacturing method of claim 16, wherein the preliminary trench is extended into the first stack when some of the contact holes are extended into the first stack.

18. The manufacturing method of claim 16, further comprising:
replacing the first material layers and the third material layers with fifth material layers through the slit; and
forming a slit structure in the slit.

19. The manufacturing method of claim 16, wherein the preliminary trench exposes the third material layers through the bottom surface with the stair shape.

20. The manufacturing method of claim 16, wherein in the extending some of the contact holes into the first stack, the contact holes are extended to have different depths.

21. The manufacturing method of claim 16, wherein the slit includes a lower sidewall having a wave shape and an upper sidewall having a straight line shape.
